(19) United States
(12) Patent Application Publication
(10) Pub. No.: US 2014/0340663 A1
(43) Pub. Date: Nov. 20, 2014

(54) Apparatus for Monitoring a Lithographic Patterning Device

(71) Applicants: Luigi Scaccabarozzi, Valkenswaard (NL); Vadim Yevgenyevich Banine, Deurne (NL); Bernardus Antonius Johannes Luttikhuis, Nuenen (NL); Roelof Koole, Eindhoven (NL); Hendrikus Jan Wondergem, Veldhoven (NL); Petrus Carolus Johannes Graat, Geldrop (NL)

(72) Inventors: Luigi Scaccabarozzi, Valkenswaard (NL); Vadim Yevgenyevich Banine, Deurne (NL); Bernardus Antonius Johannes Luttikhuis, Nuenen (NL); Roelof Koole, Eindhoven (NL); Hendrikus Jan Wondergem, Veldhoven (NL); Petrus Carolus Johannes Graat, Geldrop (NL)

(73) Assignee: ASML Netherlands B.V., Veldhoven (NL)

(21) Appl. No.: 14/345,118

(22) PCT Filed: Aug. 21, 2012
(86) PCT No.: PCT/EP2012/066223

§ 371 Date: Mar. 14, 2014

Related U.S. Application Data
(60) Provisional application No. 61/535,571, filed on Sep. 16, 2011.
(60) Provisional application No. 61/567,338, filed on Dec. 6, 2011.

(51) Int. Cl. G03F 7/20

(52) U.S. Cl. CPC G03F 7/70783; G03F 7/70141
USPC 355/67

(57) ABSTRACT

A lithographic patterning device deformation monitoring apparatus (38) comprising a radiation source (40), an imaging device (42), and a processor (50). The radiation source being configured to direct a plurality of beams of radiation (41) with a predetermined diameter towards a lithographic patterning device (MA) such that they are reflected by the patterning device. The imaging detector configured to detect spatial positions of the radiation beams (41′) after they have been reflected by the patterning device. The processor configured to monitor the spatial positions of the radiation beams and thereby determine the presence of a patterning device deformation. The imaging detector has an collection angle which is smaller than a minimum angle of diffraction of the radiation beams.

### CROSS REFERENCE TO RELATED APPLICATIONS

This application is related to U.S. Provisional App. No. 61/535,571, which was filed on Sep. 16 2011 and U.S. Provisional App. No. 61/567,338, which was filed on Dec. 6, 2011, which are incorporated by reference herein in its entirety.

### FIELD

The present invention relates to a lithographic apparatus and to a patterning device monitoring apparatus and method.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k₁ is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k₁.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm, or example within the range of 5-10 nm such as 6.7 nm or 6.8 nm. Possible sources include, for example, laser-produced plasma sources, discharge plasma sources, or sources based on synchrotron radiation provided by an electron storage ring.

EUV radiation may be produced using a plasma. A radiation system for producing EUV radiation may include a laser for exciting a fuel to provide the plasma, and a source collector module for containing the plasma. The plasma may be created, for example, by directing a laser beam at a fuel, such as particles of a suitable material (e.g. tin), or a stream of a suitable gas or vapor, such as Xe gas or Li vapor. The resulting plasma emits output radiation, e.g., EUV radiation, which is collected using a radiation collector. The radiation collector may be a mirrored normal incidence radiation collector, which receives the radiation and focuses the radiation into a beam. The source collector module may include an enclosing structure or chamber arranged to provide a vacuum environment to support the plasma. Such a radiation system is typically termed a laser produced plasma (LPP) source. The radiation collector may also be a mirrored grazing incidence collector typically used in discharge produced plasma (DPP) source.

An EUV mask (or other patterning device) may be held on a mask support structure, for example using electrostatic attraction. The mask support structure may be referred to as a chuck. The interior of the EUV lithographic apparatus may be held at a vacuum during operation of the lithographic apparatus. Nevertheless, contamination particles may be present within the lithographic apparatus. If a contamination particle were to become trapped between a mask and a mask support structure then this could cause the reticle to become distorted. This deformation of the mask may reduce the accuracy with which a pattern on the mask may be projected onto a substrate (a localised deformation of the pattern may occur in the vicinity of the contamination particle). The deformation may be sufficiently severe that the lithographic apparatus cannot project the pattern with a required accuracy.

In order to reduce the likelihood that contamination particles cause deformation of the mask, the mask support structure may be provided with an array of protrusions known as burls. The burls provide a contact surface which receives the mask and in addition provide a volume within which contamination particles may reside without causing deformation of the mask. The burls reduce the likelihood that a contamination particle causes deformation of the mask.

Some contamination particles may be sufficiently soft that they are compressed by the mask when the mask is clamped to the mask support structure, and do not give rise to significant deformation of the mask.

Despite the use of burls, and despite the fact that some contamination particles may be soft, the possibility remains that a contamination particle may cause undesirable deformation of the mask (or other patterning device).

### SUMMARY

It is desirable to provide an apparatus to monitor for deformation of a patterning device (e.g. a mask).

According to a first aspect of the present invention, there is provided a lithographic patterning device deformation monitoring apparatus comprising a radiation source configured to direct a plurality of beams of radiation with a predetermined diameter towards a lithographic patterning device such that they are reflected by the patterning device, an imaging detector configured to detect spatial positions of the radiation beams after they have been reflected by the patterning device, and a processor configured to monitor the spatial positions of the radiation beams and thereby determine the presence of a patterning device deformation, wherein the imaging detector has an collection angle which is smaller than a minimum angle of diffraction of the radiation beams.

The predetermined diameter of the radiation beams may be less than 1000 microns, may be less than 500 microns, may be less than 200 microns, or may be less than 100 microns.

The plurality of beams of radiation may comprise three or more radiation beams separated in a given direction.

The plurality of beams of radiation may comprise a two dimensional array of radiation beams.

The imaging detector may be located 100 mm or more, 200 mm or more, 500 mm ore more, or lm or more from a support structure configured to hold the patterning device.

The imaging detector may be configured to have an operational area which measures less than 1 inch across.

The radiation source may comprise an etalon which is configured to convert a beam of radiation into a plurality of beams of radiation which propagate substantially parallel to one another.

The radiation source may be one of a plurality of radiation sources and the imaging detector may be one of a plurality of imaging detectors. The apparatus may further comprise a controller which is configured to operate each radiation source and associated imaging detector in series.

The radiation source may be one of a plurality of radiation sources and the apparatus may further comprise a controller which is configured to operate each radiation source in series and to receive detected radiation signals from selected parts of the imaging detector in series.

The imaging detector may be a CCD array.

The patterning device may be a mask.

According to a second aspect of the present invention there is provided a lithographic apparatus comprising the mask deformation monitoring apparatus of the first aspect of the present invention, and further comprising an illumination system configured to condition a radiation beam, a support structure constructed to support a patterning device, the patterning device being capable of imparting the radiation beam with a pattern in its cross-section to form a patterned radiation beam, a substrate table constructed to hold a substrate, and a projection system configured to project the patterned radiation beam onto a target portion of the substrate.

The support structure may support a patterning device, and the predetermined diameter of the radiation beams may be no more than ten times bigger than the pitch of the largest periodic structure present on the patterning device.

According to a third aspect of the present invention there is provided a lithographic mask deformation monitoring apparatus comprising a radiation source configured to direct a plurality of beams of radiation with a predetermined diameter towards a lithographic mask such that they are reflected by the lithographic mask, an imaging detector configured to detect spatial positions of the beams after they have been reflected by the lithographic mask, and a processor configured to monitor the spatial positions of the beams and thereby determine the presence of a mask deformation, wherein the imaging detector has an collection angle which is less than or equal to +/−5°.

According to a fourth aspect of the present invention there is provided a method of determining whether or not a patterning device is suffering from deformation, the method comprising directing a plurality of beams of radiation towards a lithographic patterning device such that they are reflected by the patterning device, using an imaging detector to detect spatial positions of the radiation beams after they have been reflected by the patterning device, and monitoring the spatial positions of the radiation beams and thereby determining the presence of a patterning device deformation, wherein the imaging detector has an collection angle which is smaller than a minimum angle of diffraction of the radiation beams.

The method may further comprise monitoring the spatial positions of the radiation beams when a first clamping force is being used to clamp the patterning device to a support structure, and then subsequently monitoring the spatial positions of the radiation beams when a second different clamping force is being used to clamp the patterning device to the support structure. The clamping force may be electrostatic attraction.

The method may comprise integrating measured radiation beam separations as a function of the relative position between the radiation beam sources and the patterning device, and using the integrated radiation beam separations to obtain a height profile of the patterning device.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 depicts a lithographic apparatus according to an embodiment of the present invention.

FIG. 2 is a more detailed view of the lithographic apparatus, including a discharge produced plasma (DPP) source collector module.

FIG. 3 is a view of an alternative source collector module of the apparatus of FIG. 1, the alternative being a laser produced plasma (LPP) source collector module.

FIG. 4 is a schematic illustration of a mask deformation monitoring apparatus according to an embodiment of the present invention.

FIG. 5 is a graph which shows variation of diffraction angle as a function of diffracting structure period.

FIG. 6 is a schematic illustration of a mask deformation monitoring apparatus according to an alternative embodiment of the present invention.

FIGS. 7a-e illustrate a height map of an area of a mask as measured with a mask deformation monitoring apparatus according to an embodiment of the invention, the presence of a particle, respectively for an electrostatic chuck clamping voltage of 1000V, 1500V, 2000V, 2500V and 3200V.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

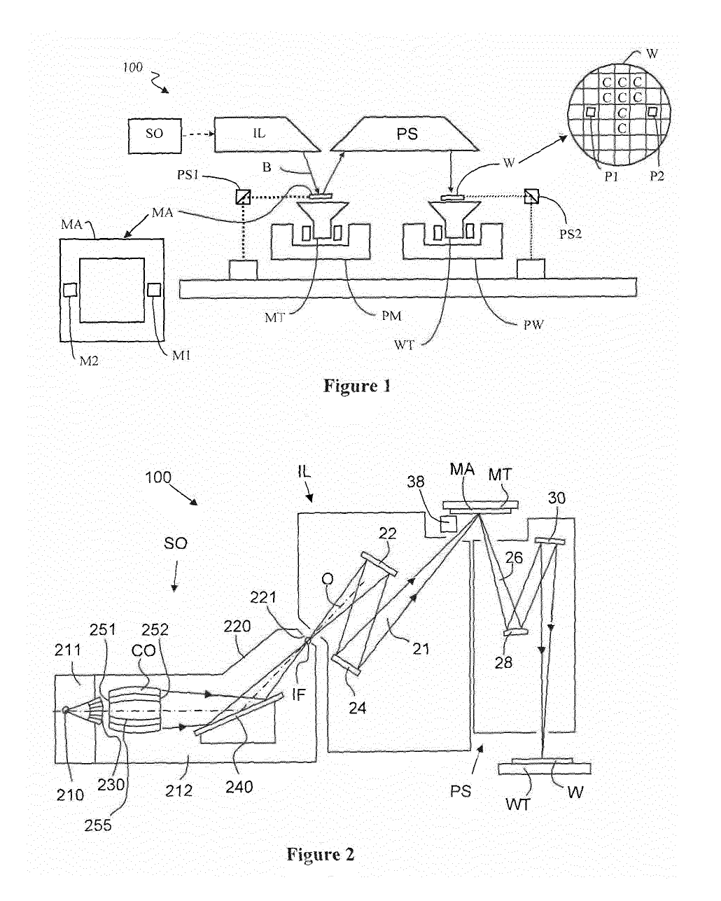

FIG. 1 schematically depicts a lithographic apparatus 100 including a source collector module SO according to one embodiment of the present invention. The apparatus comprises an illumination system (illuminator) IL configured to condition a radiation beam B (e.g. EUV radiation), a support structure (e.g. a mask support structure) MT constructed to support a patterning device (e.g. a mask or a reticle) MA and connected to a first positioner PM configured to accurately position the patterning device, a substrate table (e.g. a wafer table) WT constructed to hold a substrate (e.g. a resist-coated wafer) W and connected to a second positioner PW configured to accurately position the substrate; and a projection system (e.g. a reflective projection system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g. employing a reflective mask).

The lithographic apparatus may be of a type having two (dual stage) or more substrate tables (and/or two or more mask support structures). In such “multiple stage” machines the additional tables may be used in parallel, or preparatory steps may be carried out on one or more tables while one or more other tables are being used for exposure.

Referring to FIG. 1, the illuminator IL receives an extreme ultra violet (EUV) radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g. EUV radiation, which is collected using a radiation collector, disposed in the source collector module. The laser and the source collector module may be separate entities, for example when a CO₂ laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as a-outer and a-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g. mask) MA, which is held on the support structure (e.g. mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using mask alignment marks M1, M2 and substrate alignment marks P1, P2.

The depicted apparatus could be used in at least one of the following modes:

1. In step mode, the support structure (e.g. mask support structure) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the support structure (e.g. mask support structure) MT and the substrate table WT are scanned synchronously while a pattern imparted to the radiation beam is projected onto a target portion C (i.e. a single dynamic exposure). The velocity and direction of the substrate table WT relative to the support structure (e.g. mask support structure) MT may be determined by the (de-)magnification and image reversal characteristics of the projection system PS.

3. In another mode, the support structure (e.g. mask support structure) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

FIG. 2 shows the apparatus 100 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contaminant trap 230 may also include a gas barrier or a combination of a gas barrier and a channel structure. The contaminant trap or contaminant barrier 230 further indicated herein at least includes a channel structure, as known in the art.

The collector chamber 212 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the wafer stage or substrate table WT. A mask deformation monitoring apparatus 38 according to an embodiment of the present invention is located adjacent to the mask support structure MT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be 1-6 additional reflective elements present in the projection system PS than shown in FIG. 2.

Collector optic CO, as illustrated in FIG. 2, is depicted as a nested collector with grazing incidence reflectors 253, 254 (adjacent to reflector 255 in FIGS. 2) and 255, just as an example of a collector (or collector mirror). The grazing incidence reflectors 253, 254 and 255 are disposed axially symmetric around an optical axis O and a collector optic CO of this type is preferably used in combination with a discharge produced plasma source, often called a DPP source.

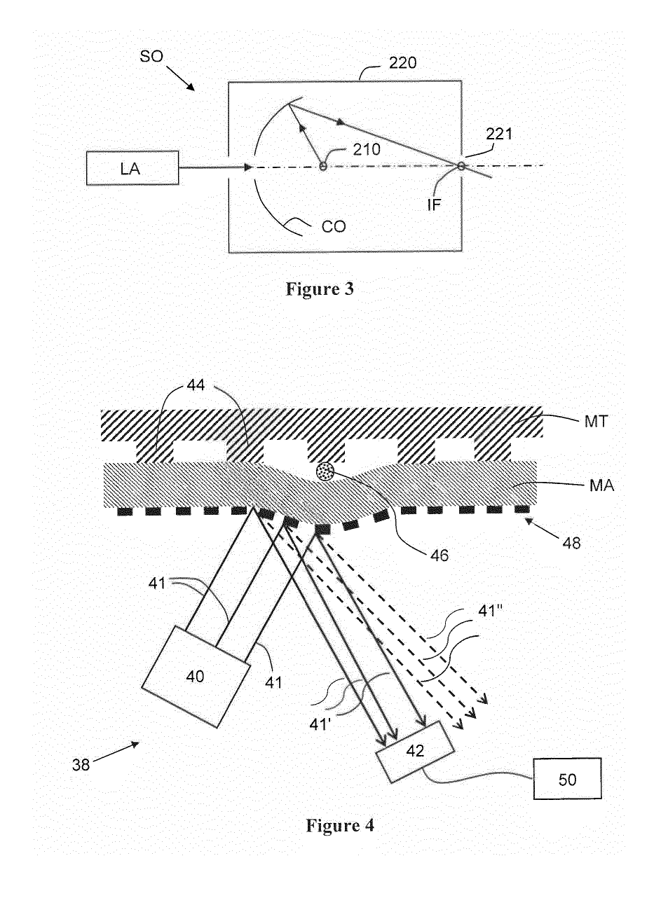

Alternatively, the source collector module SO may be part of an LPP radiation system as shown in FIG. 3. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

FIG. 4 schematically shows a mask deformation monitoring apparatus 38 according to an embodiment of the present invention. The apparatus 38 comprises a radiation source 40 configured to emit nine substantially parallel beams of radiation 41. The beams of radiation are provided as a rectangular array. The rectangular array extends out of the plane of FIG. 4, and consequently only three of the nine beams of radiation are shown in FIG. 4. The apparatus further comprises an imaging detector 42 which is configured to detect the beams of radiation after they have been reflected from a mask MA.

Part of a mask MA is shown schematically in FIG. 4. The mask MA is held on a mask support structure MT, part of which is also shown schematically in FIG. 4. The mask support structure MT includes a plurality of burls 44 which together provide a mask receiving surface. A contamination particle 46 is located between one of the burls 44 and a back surface of the mask MA. The contamination particle 46 causes an undesirable deformation of the mask MA which is represented schematically in FIG. 4 by curvature of the mask. A pattern 48 is present on the mask MA, the pattern being represented schematically by a series of blocks.

As may be seen from FIG. 4, the radiation beams 41 are incident upon the mask MA and are reflected as corresponding reflected radiation beams 41′ towards the imaging detector 42. The spatial positions at which the reflected radiation beams 41′ are incident upon the imaging detector 42 are influenced by the mask deformation caused by the contamination particle 46. When the radiation beams 41 are incident upon the mask MA they are equally spaced. If the mask MA was not distorted then the reflected radiation beams 41′ would be equally spaced when they were incident upon the imaging detector 42. However, the deformation of the mask MA causes a modification of the angles at which the radiation beams are reflected from the mask, and as a result the reflected radiation beams 41′ are not equally spaced when they are incident upon the imaging detector 42. Instead, one or more of the reflected radiation beams 41′ are displaced. This is represented schematically in FIG. 4 by a displacement to the left of the middle radiation beam of the reflected radiation beams 41′.

A processor 50 is configured to determine the positions of the reflected radiation beams 41′ when they are incident upon the imaging detector 42. The centroid (i.e. the geometric center of a given shape) of a reflected radiation beam 41′ may for example be recorded as that radiation beam's position. The processor 50 determines the displacement of the radiation beams, and uses this displacement to determine whether or not the mask MA is distorted. One way in which the displacement of the reflected radiation beams 41′ may be determined is by comparing the positions of the radiation beams on the imaging detector with the positions of the radiation beams after reflection from an not deformed reflector (e.g. a flat mask). Other methods of determining the displacement of radiation beams 41 may be used.

The radiation beams 41 may be moved over the mask MA, for example through scanning movement of the mask (and/or through scanning movement of the radiation beams). A change of the separation between two reflected radiation beams 41′ is indicative of curvature of the mask MA. Integrating the changing separation between two radiation beams as a function of the relative positions of the radiation sources and the mask allows the height profile of the mask MA to be determined. A height profile which is curved in a manner indicative of deformation caused by a contamination particle may be identified by the processor 50 (e.g. through comparison with previously measured deformation caused by contamination particles).

If the processor 50 determines that the mask MA is distorted, then the processor may determine whether or not the deformation is sufficiently large that projection of patterns from the mask by the lithographic apparatus with a desired accuracy is possible. If projection of patterns with a desired accuracy is not possible then the processor 50 may generate an output accordingly. The output may for example be a signal indicating that the mask MA should be removed from the lithographic apparatus and cleaned and/or may be a signal indicating that the lithographic apparatus should be cleaned. Cleaning of the mask MA may be an automated process which may be triggered by the output signal from the processor 50.

Radiation diffracted by the pattern 48 on the mask MA could introduce errors into the mask deformity monitoring. It is appreciated that in the presence of a pattern on the mask surface, in the area illuminated by the radiation beams 41, there may be associated with at least one of the plurality of impinging radiation beams 41 a diffracted radiation beam 41″. If all the radiation beams 41 traverse a patterned area, diffracted radiation beams 41″ may be associated with the plurality of impinging radiation beams 41. For example, a diffracted radiation beam 41″ which is incident upon the imaging detector 42 could shift the apparent centroid of the or a reflected radiation beam 41′, thereby causing the position of the reflected radiation beam 41′ to be measured incorrectly. For this reason, the mask deformation monitoring apparatus may be configured such that radiation which is diffracted by the pattern 48 on the mask MA is not incident upon the imaging detector 42 (or such that amount of diffracted radiation incident upon the imaging detector 42 is sufficiently low that it does not prevent mask deformity monitoring from being performed).

The extent to which diffracted radiation is incident upon the imaging detector 42 depends upon the collection angle of the imaging detector and upon the angles at which radiation is diffracted by the pattern 48. The collection angle of the imaging detector 42 is governed by the size of the imaging detector and the distance between the imaging detector and the mask MA. The angles at which radiation is diffracted by the pattern 48 depend upon the wavelength of the radiation and the pitch of the pattern. For a given wavelength and pattern pitch, diffracted radiation has a minimum angle. The amount of diffracted radiation present at angles which are less than the minimum angle is sufficiently low that it does not prevent mask deformity monitoring from taking place. In some instances the amount of diffracted radiation present at angles which are less than the minimum angle may be zero. In the embodiment shown in FIG. 4, radiation 41″ or radiation beams 41″ which is diffracted by the pattern is indicated by dotted lines. As is represented schematically in FIG. 4, the angle subtended by the diffracted radiation is greater than the collection angle of the imaging detector 42, and as a result the diffracted radiation is not incident upon the imaging detector. The diffracted radiation instead passes to the side of the imaging detector 42.

FIG. 5 is a graph which shows angles of diffraction of beams of radiation which will occur when radiation is incident upon a periodic structure (e.g. a pattern on a patterning device). The graph was generated for radiation having a wavelength of 1060 nm, the radiation beam having an incidence angle of 5° relative to the periodic structure (i.e. 5° away from a line perpendicular to the surface of the periodic structure). FIG. 5 shows the first five diffraction orders (i.e. orders 1-5). The diffraction orders appear as a series of lines, the thickest solid line being the first diffraction order, the thinner sold line being the second diffraction order, etc. As may be seen from FIG. 5, the angle at which diffraction of beams of radiation occurs becomes smaller as the period of the periodic structure increases.

As mentioned further above, the collection angle of the imaging detector 42 depends upon the size of the imaging detector and the distance between imaging detector and the mask MA. The collection angle of the imaging detector 42 can therefore be selected by using an imaging detector having a desired size in combination with providing a desired separation between the imaging detector and the mask support structure MT. The imaging detector 42 may for example be configured such that it has an collection angle of +/−1°. This collection angle is indicated by dotted lines A in FIG. 5.

As may be seen from FIG. 5, for an collection angle of +/−1° no diffracted radiation will be incident upon the imaging detector if the period of the diffracting periodic structure is around 50 μm or less. If the period of the diffracting periodic structure is greater than 50 μm then some diffracted radiation may be incident upon the imaging detector. For example, if the diffracting periodic structure has a period of 80 μm then first order diffracted radiation may be incident upon the imaging detector, since the first order diffracted radiation falls within the collection angle of the imaging detector. Higher order diffracted radiation continues to remain outside of the collection angle of the imaging detector and will not be incident upon the imaging detector. If the diffracting periodic structure has a period of 200 μm then first, second and third order diffracted radiation falls within the collection angle of the imaging detector and will be incident upon the imaging detector. Fourth and fifth order diffracted radiation will continue to remain outside of the collection angle of the imaging detector and will not be incident upon the imaging detector.

Based on the above it may be understood that if a mask MA comprises only patterns which have a period of less than around 50 μm, and if the imaging detector 42 has an collection angle of around +/−1° then diffracted radiation will not be incident upon the imaging detector when mask deformation monitoring is being performed. This is advantageous because if diffracted radiation were to be incident upon the imaging detector then it could introduce errors into the mask deformation monitoring. This could for example lead to the processor 50 wrongly indicating that mask deformation caused by a contamination particle is present when no mask deformation is present.

In an embodiment, some diffracted radiation may be incident upon the imaging detector during mask deformation monitoring, but the intensity of that diffracted radiation may be sufficiently low that it does not prevent the mask deformation monitoring from being performed.

The processor 50 may be configured to analyse detected radiation in the frequency domain. Where this is the case, and where some diffracted radiation is incident upon the imaging detector during mask deformation monitoring, the intensity of that diffracted radiation at frequencies being analysed by the processor 50 may be sufficiently low that it does not prevent the mask deformation monitoring from being performed.

It is possible that the mask MA includes a periodic structure which has a period sufficiently large that it could give rise to diffracted radiation which falls within the collection angle of the imaging detector. In order to mitigate against this possibility each radiation beam 41 may have a predetermined diameter which is sufficiently small that not enough periods of a large periodic structure are illuminated by the radiation beam to give rise to significant diffraction. As a rough approximation, it may be the that around 5-10 periods of a periodic structure need to be illuminated by an incident radiation beam in order to give rise to a significant amount of diffracted radiation. In this context the term “significant amount of diffracted radiation” may be interpreted as meaning sufficient diffracted radiation to introduce errors into the mask deformation monitoring (e.g. thereby preventing mask deformation monitoring from being performed). Referring again to FIG. 5, if the radiation beams 41 have a diameter of 200 μm then in order for a pattern to give rise to a significant amount of diffracted radiation that pattern would need to have a period of 40 μm or less. Radiation which is diffracted by a pattern having a period of 40 μm falls well outside of the collection angle of the imaging detector 42. The diffracted radiation is therefore not incident upon the imaging detector and does not introduce errors into the mask deformation measurement. Patterns present on a mask MA which have a period greater than 40 μm will not give rise to a significant amount of radiation diffraction, since an insufficient number of periods of the pattern will be illuminated by the radiation beam 41. Therefore, even if the mask MA includes a pattern having a period which is sufficiently large that diffracted radiation falls within the collection angle of the imaging detector and would be detected by the imaging detector, that pattern will not give rise to a significant amount of diffracted radiation and therefore will not introduce a significant error into the mask deformation measurement.

From the above it will be understood that for radiation beams 41 having a predetermined diameter, the collection angle of the imaging detector 42 may be selected to be smaller than a minimum angle of diffraction. The collection angle of the imaging detector 42 may be smaller than the minimum angle of diffraction of the radiation beams 41″ (taking into account the predetermined diameters of the radiation beams). Some diffracted radiation may be seen at angles which are less than the minimum angle of diffraction. However, the intensity of this diffracted radiation is sufficiently low that it does not prevent monitoring for mask deformities from taking place.

The angles and dimensions referred to further above are given merely as examples, and it will be appreciated that they may be varied according to the specific requirements that apply for a given lithographic apparatus. For example, the collection angle of the imaging detector 42 may be less than +/−5°, less than +/−3°, less than +/−2°, or less than +/−1°. The predetermined diameter of the radiation beams 41 may be less than 1000 μm, less than 500 μm, less than 200 μm, or less than 100 μm.

The imaging detector 42 may be located lm or more from the mask MA, may be located 500 mm or more from the mask, may be located 200 mm or more from the mask, or may be located 100 mm or more from the mask. The imaging detector 42 may be located less than 100 mm from the mask MA. Increasing the distance between the imaging detector 42 and the mask MA will reduce the collection angle of the imaging detector. The distance between the imaging detector 42 and the mask support structure MT may be considered to be an equivalent measurement to the distance between the imaging detector and the mask MA (e.g. if referring to the distance when a mask MA is not present in the lithographic apparatus).

The imaging detector 42 may for example measure ⅓ inch (8.5 mm) across, may for example measure ½ inch (12.7 mm) across, or may have some other size. The imaging detector 42 may for example measure less than 1 inch (2.5 cm) across. Reducing the size of the imaging detector 42 will reduce the collection angle of the imaging detector.

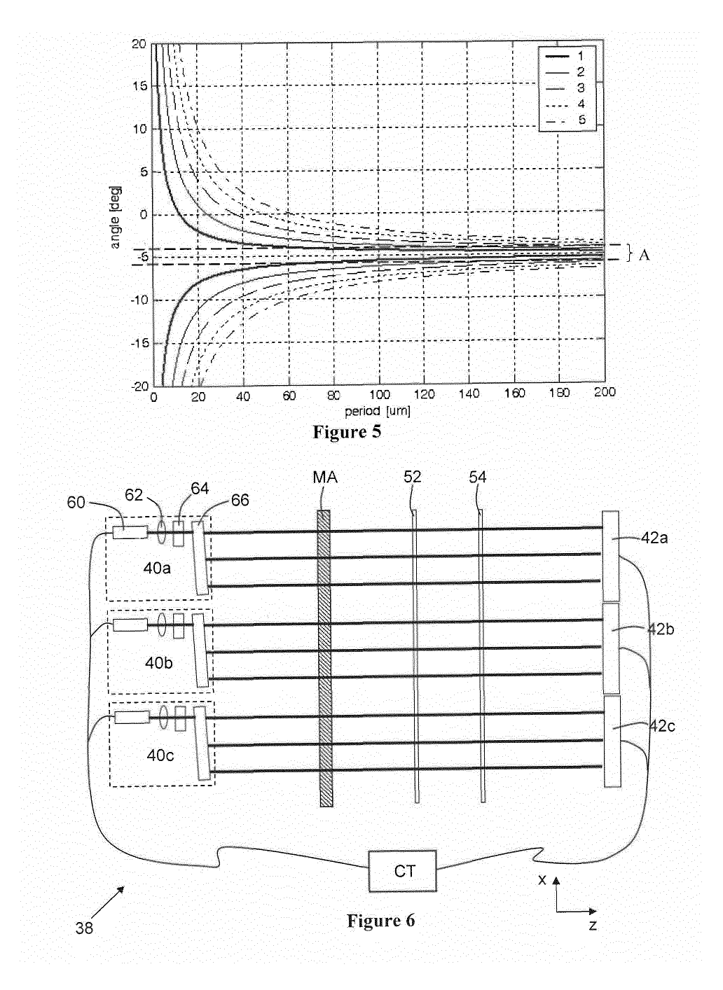

Since the collection angle of the imaging detector 42 is small, the deformation monitoring apparatus may monitor only a small area of the mask MA at any given time. The deformation monitoring apparatus may be used to monitor a substantial portion of the surface of the mask MA or even the entire surface of the mask MA, for example by scanning the monitoring apparatus relative to the mask MA and/or vice versa. However, it may be very time consuming to monitor the entire surface of the mask MA. The collection angle of the imaging detector 42 should not be increased in order to increase the area of the mask MA which is monitored at any given time, since doing so could allow a significant amount of diffracted radiation to be incident upon the imaging detector, thereby introducing errors into the deformation monitoring. Instead, a plurality of imaging detectors 42 may be provided in order to increase the speed of deformation monitoring. One way in which a plurality of imaging detectors 42 may be provided is shown schematically in FIG. 6.

In FIG. 6, a mask deformation monitoring apparatus 38 comprises three radiation sources 40a-c and three imaging detectors 42a-c, each imaging detector being configured to receive radiation emitted by a given radiation source. Each radiation source 40a-c is configured to direct nine radiation beams (three of which are shown) towards a mask MA. The radiation beams are reflected by the mask MA, although for ease of illustration they are shown as passing through the mask in FIG. 6. The monitoring apparatus further comprises a first mirror 52 and a second mirror 54, the mirrors being configured to reflect the radiation beams such that they are incident upon imaging detectors 42a-c. For ease of illustration the radiation beams are shown as passing through the mirrors 52, 54. The mirrors 52, 54 are used to fold the radiation beams in order to allow the monitoring apparatus to be shorter than the total path length travelled by the radiation beams. Although two mirrors 52, 54 are shown in FIG. 6 any number of mirrors may be used (or alternatively no mirrors may be used). One or more or the mirrors may have adjustable orientation.

Components of each of the radiation sources 40a-c are shown in FIG. 6. For ease of illustration only the components of the first radiation source 40a are labeled. The first radiation source comprises a laser 60 which is configured to generate a beam of radiation at a desired wavelength (e.g. infrared radiation, for example having a wavelength of around 1000 nm). The laser 60 may be a diode laser, a fibre laser or any other suitable type of laser. In an embodiment, the laser may be located remotely from the monitoring apparatus. Where this is the case radiation emitted by the laser may be coupled to the monitoring apparatus by an optical fibre (or other apparatus). A lens 62 is located after the laser 60. The lens 62 may for example be used to collimate the radiation beam emitted by the laser 60, or may be used to apply some other modification to the radiation beam. Although a single lens 62 is shown in FIG. 6, any number of lenses may be located after the laser 60.

An etalon 64 is located after the lens 62. The etalon 64 may for example be a Fabry-Perot etalon, or may be any other suitable type of etalon. The etalon 64 may comprise two reflective surfaces which are spaced apart from one another, the reflective surfaces being configured to convert the radiation beam into three radiation beams which propagate substantially parallel to one another. The reflective surface which is furthest from the laser 60 is partially transmissive, thereby allowing the three radiation beams to leave the etalon 64. The etalon 64 converts radiation beam into three radiation beams which are spaced apart from one another in the y-direction.

A second etalon 66 is located after the first etalon. The second etalon 66 may for example also be a Fabry-Perot etalon, or may be any other suitable type of etalon. The second etalon 66 comprises two reflective surfaces which are spaced apart from one another, the reflective surfaces being configured to convert each incident radiation beam into three radiation beams which are separated in the x-direction. The three radiation beams separated in the x-direction propagate substantially parallel to one another.

The combination of the first and second etalons 64, 66 converts the radiation beam into nine radiation beams which propagate substantially parallel to one another. The nine radiation beams may be arranged as a rectangular array.

Other radiation sources 40b, 40c of FIG. 6 have the same construction as the first radiation source 40a. The radiation source 40 of FIG. 4 may have the same construction as the first radiation source 40a.

The monitoring apparatus may include a controller CT which may be configured to operate each of the radiation sources 40a-c and associated imaging detectors 42a-c in series. This avoids the possibility that, for example, radiation emitted by the first radiation source 40a is diffracted by a pattern on the mask MA and is detected by the second imaging detector 40b or the third imaging detector 40c.

Although three radiation sources 40a-c and three imaging detectors 42a-c are shown in FIG. 6, any desired number of radiation sources and imaging detectors may be provided. For example, a sufficient number of radiation sources and imaging detectors may be provided to extend fully across a mask MA in a non-scanning direction of the lithographic apparatus (or equivalently to extend fully across the portion of a mask support structure which is configured to receive a mask during operation of the lithographic apparatus). Monitoring of the mask MA for deformation may then be performed by scanning the mask in the scanning direction such that the entire mask (or the entire portion of the mask which receives radiation during operation of the lithographic apparatus) passes beneath the area illuminated by radiation beams of the monitoring apparatus.

In an alternative embodiment (not illustrated), instead of having a plurality of imaging detectors a single larger imaging detector may be provided. Where this is done, detected radiation signals may be received from selected parts of the imaging detector in series, thereby limiting the collection angle of the imaging detector at any given moment in time. The alternative embodiment may for example be similar to that shown in FIG. 6, but with a single imaging detector having three parts instead of three separate imaging detectors 42a-c. The controller CT may receive detected radiation signals from a first part of the single imaging detector when the first radiation source 40a is operating, detected radiation signals from second and third parts of the single imaging detector being ignored by the controller. The first part of the single imaging detector may have an area which corresponds with 42a in FIG. 6. The controller may receive detected radiation signals from a second part of the single imaging detector when the second radiation source 40b is operating, etc. In general, the controller may be configured to receive detected radiation signals from selected parts of the imaging detector in series. The selected parts of the imaging detector may have dimensions which correspond with the imaging detector dimensions mentioned further above, or may have any other suitable dimensions.

Although described embodiments of the present invention include radiation sources which provide a rectangular array of nine radiation beams, radiation sources which provide any suitable number of radiation beams may be used. For example, radiation sources which provide two radiation beams may be used, changes of the separation between the radiation beams being used to monitor for deformation of the mask MA. A radiation source which provides two radiation beams separated in the x-direction and a radiation source which provides two radiation beam is separated in the y-direction may for example be used.

Using three radiation beams separated in a given direction is advantageous compared with using two radiation beams, because it allows three different beam separation measurements to be performed whereas using two radiation beams allows only one radiation beam separation measurement be performed. Referring to the first imaging detector 42a in FIG. 6 for example, the separation between the uppermost radiation beam and the lowermost radiation beam may be measured, the separation between the uppermost radiation beam and the middle radiation beam may be measured, and the separation between the middle radiation beam and the lowermost radiation beam may be measured. Since separation between the radiation beams is generated by an etalon, in the absence of a mask deformation the radiation beams may be expected to all have the same separation. This may allow some cross-checking between different beam separation measurements to be performed. Redundancy and extra data provided by using three or more beams in a given measurement direction may improve the accuracy with which mask deformations may be identified.

Although FIG. 6 shows radiation beams which are separated in the x-direction, the above may also apply to radiation beams which are separated in the y-direction.

Some radiation beams may be separated in a direction which is parallel to the scanning direction of the lithographic apparatus (e.g. the y-direction), and other radiation beams may be separated in a direction (e.g. the x-direction) which is transverse to the scanning direction of the lithographic apparatus. Alternatively, radiation beams may be separated in any desired direction.

Four or more radiation beams separated in a given direction may be used.

The imaging detectors 42, 42a-c may for example be CCD arrays, or may be any other form of imaging detector.

The processor 50 (as shown in FIG. 4) may for example form part of a computer. The lithographic mask deformation monitoring apparatus may include reference data, for example indicating the positions of radiation beams which would be expected at the imaging detector(s) if the mask MA were to be flat (i.e. not deformed). The reference data may for example be obtained using a reference surface which is known to be particularly flat.

The mask support structure MT may use electrostatic clamping to secure the mask MA to the mask support structure, wherein a voltage is applied to the mask support structure to provide the clamping. The latter voltage is referred to as the clamping voltage. Where this is the case the clamping voltage applied to the mask support structure may be changed during operation of the mask deformation monitoring apparatus. Changing the clamping voltage will cause a size or diameter of a local mask deformation caused by the contamination particle 46 (see FIG. 4) to change. A higher voltage will draw the mask MA more tightly to the mask support structure MT and will reduce the diameter of the mask deformation. Conversely, a lower voltage will increase the diameter of the mask deformation. In contrast to this, changing the clamping voltage will not significantly affect the pattern 48 on the mask MA. Therefore, for a given location on the mask or for a given area of the mask illuminated by radiation beams 41 of the deformation monitoring apparatus, a deformation measurement may be performed for two different clamping voltages and the resulting measured signals may be subtracted from one another, reducing or eliminating measurement effects arising from the pattern 48 on the mask.

It is appreciated that similarly the deformation measurement may be performed for more than two different clamping voltages. For example the clamping voltage applied to the mask support structure can be subsequently changed to a series of different, incremental voltage-values, and the mask deformation monitoring apparatus can be used to obtain mask deformation data for each clamping voltage of the series, such that a corresponding series of mask deformation data is obtained. The series of mask deformation data can be used to obtain differential mask deformation data in accordance with corresponding differences between two respective series of mask deformation data. Such a measurement method is referred to, hereinafter, by a differential measurement.

The aforementioned differential measurement method yields a relatively high signal to noise ratio in comparison with an absolute measurement where at a single value of the clamping voltage an area is monitored for a localized deformation of the mask MA. Any background noise in such an absolute measurement may be due to, for example, a beam 41 sampling an area of the mask including a transition from an unpatterned area to a patterned area. Compared to a beam 41 sampling solely an unpatterned area of the mask, the reflected beam will have less intensity and will have a different spatial intensity distribution at the detector 42. Consequently a shift of the measured centroid of the beam at the detector 42 may lead to noise in a measurement of, for example, a curvature of a local mask deformation. The differential measurement enables obtaining a desired sensitivity required for the measurements (e.g. less than 1 nm height variation over 5 mm length along the reticle surface). It is appreciated that the above described differential measurement can be executed within the lithographic apparatus.

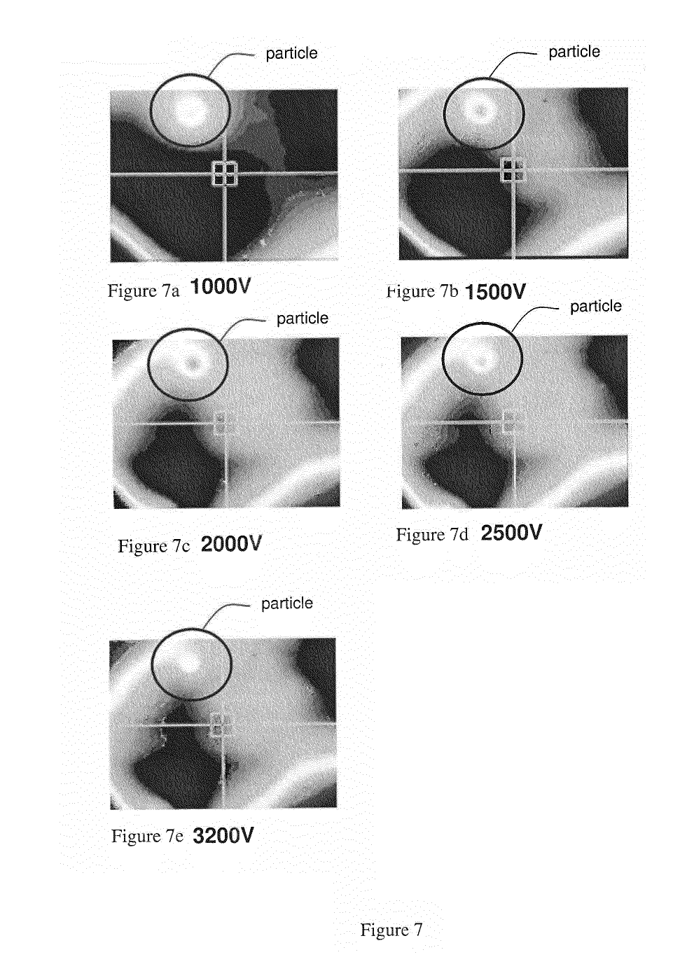

In FIG. 7 results of a differential measurement for detecting a particle are shown. In each of FIGS. 7a-e a portion of a reticle surface monitored for a localized deformation using the deformation monitoring apparatus is shown, and measured height deviations in absolute sense are shown in a number of greytoned areas. Between two successive figures, e.g. between FIG. 7b and FIG. 7c, the clamping voltage is increased by 500 V. It can be seen that in particular a local deformation due to a particle and a corresponding local surface curvature changes strongly as a function of clamping voltage, whereas a curvature of the surrounding area remains practically unaffected. Hence, the differential measurement method enables distinguishing between a height profile due to a particle and a height profile inherent to the mask.

In the Table below, an example of values of a local mask surface deformation in terms of height (normal to the reticle surface) and average full-width half-maximum values of a diameter of the local deformation due to a trapped particle are listed, for the number of successively increasing clamping voltages as mentioned in FIGS. 7a-e.

| voltage [V] | max. local deformation height [nm] | average FWHM [mm] |
|---|---|---|
| 1000 | 183 | 30.6 |
| 1500 | 103 | 23.2 |
| 2000 | 71 | 18.1 |
| 2500 | 56 | 16.1 |
| 3200 | 46 | 14.9 |

In embodiments in which other forms of clamping are used to secure the mask

MA to the mask table MT, the clamping force used to clamp the mask MA may be varied in a similar manner to varying the electrostatic clamping voltage.

In illustrated embodiments of the present invention the radiation beams subtend a near normal incidence angle with the mask (e.g.)5°. However, the radiation beams may subtend any suitable angle with the mask. The radiation beams may for example subtend a grazing incidence angle with the mask.

The term “collection angle” is used in the above description to define the angle over which the imaging detector receives radiation. The collection angle may be considered to be an angle measured relative to an axis which extends from the point of incidence of a radiation beam onto a flat mask MA to the centre of the imaging detector 42 (the angle being measured at the mask MA end of the axis).

Although described embodiments of the present invention refer to deformation of the mask MA being caused by a contamination particle 46 being trapped between the mask and the mask support structure MT, embodiments of the present invention may be used to monitor for mask deformation arising for other reasons. For example, embodiments of the present invention may be used to monitor for mask deformation caused by temperature variations. Where this is done, a reference measurement of the mask may be performed when the mask has a given temperature, deformation of the mask relative to the reference being measured as the temperature of the mask changes.

Although described embodiments of the present invention refer to diffraction which occurs due to periodic patterns on a mask MA, diffraction may also occur for non-periodic patterns. In this case an equivalent to the pattern period may be determined via a Fourier transform of the pattern. Embodiments of the present invention may be used in connection with any mask which gives rise to diffraction of radiation.

Embodiments of the present invention may monitor for deformation of a mask, generating an output signal when mask deformation is found. Embodiments of the present invention may measure the size of the mask deformation and/or some other property of the mask deformation. An output signal from the apparatus may include information relating to the size and/or some other property of the mask deformation, or may merely indicate the presence of a mask deformation.

Embodiments of the present invention may be used to monitor for a mask deformation which has a height of a few nanometres and which has a width of a few millimetres.

Although described embodiments of the present invention refer to a mask MA, the present invention may be used to monitor for deformation in any lithographic patterning device. Examples of lithographic patterning devices are given further above.

Embodiments of the present invention may include a support structure which is configured to support a patterning device other than a mask.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the present invention in the context of optical lithography, it will be appreciated that the present invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The term “lens”, where the context allows, may refer to any one or combination of various types of optical components, including refractive, reflective, magnetic, electromagnetic and electrostatic optical components.

The term “EUV radiation” may be considered to encompass electromagnetic radiation having a wavelength within the range of 5-20 nm, for example within the range of 13-14 nm, or example within the range of 5-10 nm such as 6.7 nm or 6.8 nm.

Cartesian coordinates have been used in the above description in order to facilitate description of the present invention. The Cartesian coordinates should not be interpreted as meaning that the apparatus or any feature of the apparatus must have a particular orientation.

While specific embodiments of the present invention have been described above, it will be appreciated that the present invention may be practised otherwise than as described. For example, the present invention may take the form of a computer program containing one or more sequences of machine-readable instructions describing a method as disclosed above, or a data storage medium (e.g. semiconductor memory, magnetic or optical disk) having such a computer program stored therein. The descriptions above are intended to be illustrative, not limiting. Thus it will be apparent to one skilled in the art that modifications may be made to the present invention as described without departing from the scope of the claims set out below.

It is to be appreciated that the Detailed Description section, and not the

Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined in accordance with the following clauses and claims and their equivalents.

### Clauses

1. A lithographic patterning device deformation monitoring apparatus comprising:
a radiation source configured to direct a plurality of beams of radiation with a predetermined diameter towards a lithographic patterning device such that they are reflected by the patterning device,
an imaging detector configured to detect spatial positions of the radiation beams after they have been reflected by the patterning device, and
a processor configured to monitor the spatial positions of the radiation beams and thereby determine the presence of a patterning device deformation,
wherein the imaging detector has an collection angle which is smaller than a minimum angle of diffraction of the radiation beams.

2. The apparatus of clause 1 wherein the plurality of beams of radiation having a predetermined diameter are collimated to propagate substantially parallel to one another.

3. The apparatus of clause 1, wherein the predetermined diameter of the radiation beams is less than 1000 microns.

4. The apparatus of clause 1, wherein the plurality of beams of radiation comprises three or more radiation beams separated in a given direction.

5. The apparatus of clause 1, wherein the plurality of beams of radiation comprises a two dimensional array of radiation beams.

6. The apparatus of clause 1, wherein the imaging detector is located 100 mm or more from a support structure configured to hold the patterning device.

7. The apparatus of clause 1, wherein the imaging detector is configured to have an operational area at any given moment in time which measures less than 1 inch across.

8. The apparatus of clause 1, wherein the radiation source comprises an etalon which is configured to convert a beam of radiation into a plurality of beams of radiation which propagate substantially parallel to one another.

9. The apparatus of clause 1, wherein the radiation source is one of a plurality of radiation sources and the imaging detector is one of a plurality of imaging detectors, wherein the apparatus further comprises a controller which is configured to operate each radiation source and associated imaging detector in series.

10. The apparatus of clause 1, wherein the radiation source is one of a plurality of radiation sources and the apparatus further comprises a controller which is configured to operate each radiation source in series and to receive detected radiation signals from selected parts of the imaging detector in series.

11. The apparatus of clause 1, wherein the imaging detector is a CCD array.

12. The apparatus of clause 1, wherein the patterning device is a mask.

13. A lithographic apparatus comprising:
a patterning device deformation monitoring apparatus, comprising:
   a radiation source configured to direct a plurality of beams of radiation with a predetermined diameter towards a lithographic patterning device such that they are reflected by the patterning device,
   an imaging detector configured to detect spatial positions of the radiation beams after they have been reflected by the patterning device, and
   a processor configured to monitor the spatial positions of the radiation beams and thereby determine the presence of a patterning device deformation,
   wherein the imaging detector has an collection angle which is smaller than a minimum angle of diffraction of the radiation beams; and
an illumination system configured to condition a radiation beam,
a support structure constructed to support a patterning device, the patterning device being capable of imparting the radiation beam with a pattern in its cross-section to form a patterned radiation beam,
a substrate table constructed to hold a substrate, and
a projection system configured to project the patterned radiation beam onto a target portion of the substrate.

14. The lithographic apparatus of clause 13, wherein the support structure supports a patterning device, and wherein the predetermined diameter of the radiation beams is no more than ten times bigger than the pitch of the largest periodic structure present on the patterning device.

15. A lithographic patterning device deformation monitoring apparatus comprising:
a radiation source configured to direct a plurality of beams of radiation with a predetermined diameter towards a lithographic patterning device such that they are reflected by the lithographic patterning device,
an imaging detector configured to detect spatial positions of the beams after they have been reflected by the lithographic patterning device, and
a processor configured to monitor the spatial positions of the beams and thereby determine the presence of a patterning device deformation,
wherein the imaging detector has an collection angle which is less than or equal to +/−5°.

16. A method of determining whether or not a patterning device is suffering from deformation, the method comprising:
directing a plurality of beams of radiation towards a lithographic patterning device such that they are reflected by the patterning device,
using an imaging detector to detect spatial positions of the radiation beams after they have been reflected by the patterning device, and
monitoring the spatial positions of the radiation beams and thereby determining the presence of a patterning device deformation,
wherein the imaging detector has an collection angle which is smaller than a minimum angle of diffraction of the radiation beams.

1. A lithographic patterning device deformation monitoring apparatus comprising:
a radiation source configured to direct a plurality of beams of radiation with a predetermined diameter towards a lithographic patterning device such that they are reflected by the patterning device,
an imaging detector configured to detect spatial positions of the radiation beams after they have been reflected by the patterning device, and
a processor configured to monitor the spatial positions of the radiation beams and thereby determine the presence of a patterning device deformation,
wherein the imaging detector has an collection angle which is smaller than a minimum angle of diffraction of the radiation beams.

2. The apparatus of claim 1, wherein the plurality of beams of radiation having a predetermined diameter are collimated to propagate substantially parallel to one another.

3. The apparatus of claim 1, wherein the predetermined diameter of the radiation beams is less than 1000 microns.

4. The apparatus of claim 1, wherein the plurality of beams of radiation comprises three or more radiation beams separated in a given direction.

5. The apparatus of claim 1, wherein the plurality of beams of radiation comprises a two dimensional array of radiation beams.

6. The apparatus of claim 1, wherein the imaging detector is located 100mm or more from a support structure configured to hold the patterning device.

7. The apparatus of claim 1, wherein the imaging detector is configured to have an operational area at any given moment in time which measures less than 1 inch across.

8. The apparatus of claim 1, wherein the radiation source comprises an etalon which is configured to convert a beam of radiation into a plurality of beams of radiation which propagate substantially parallel to one another.

9. The apparatus of claim 1, wherein the radiation source is one of a plurality of radiation sources and the imaging detector is one of a plurality of imaging detectors, wherein the apparatus further comprises a. controller which is configured to operate each radiation source and associated imaging detector in series.

10. The apparatus of claim 1, wherein the radiation source is one of a plurality of radiation sources and the apparatus further comprises a controller which is configured to operate each radiation source in series and to receive detected radiation signals from selected parts of the imaging detector in series.

11. A lithographic apparatus comprising:
a patterning device deformation monitoring apparatus comprising:
a radiation source configured to direct a plurality of beams of radiation with a predetermined diameter towards a lithographic patterning device such that they are reflected by the patterning device,
an imaging detector configured to detect spatial positions of the radiation beams after they have been reflected by the patterning device, and
a processor configured to monitor the spatial positions of the radiation beams and thereby determine the presence of a patterning device deformation,
wherein the imaging detector has an collection angle which is smaller than a minimum angle of diffraction of the radiation beams.

12. The lithographic apparatus according to claim 11, further comprising one or more of the following components:
an illumination system configured to condition a radiation beam,
a support structure constructed to support the patterning device, the patterning device being capable of imparting the radiation beam with a pattern in its cross-section to form a patterned radiation beam,
a substrate table constructed to hold a substrate, and
a projection system configured to project the patterned radiation beam onto a target portion of the substrate.

13. The lithographic apparatus of claim 12, wherein the support structure supports the patterning device, and wherein the predetermined diameter of the radiation beams is no more than ten times bigger than the pitch of the largest periodic structure present on the patterning device.

14. A lithographic patterning device deformation monitoring apparatus comprising:
a radiation source configured to direct a plurality of beams of radiation with a predetermined diameter towards a lithographic patterning device such that they are reflected by the lithographic patterning device,
an imaging detector configured to detect spatial positions of the beams after they have been reflected by the lithographic patterning device, and
a processor configured to monitor the spatial positions of the beams and thereby determine the presence of a patterning device deformation,
wherein the imaging detector has an collection angle which is less than or equal to +/−5°.

15. A method of determining whether or not a patterning device is suffering from deformation, the method comprising:
directing a plurality of beams of radiation towards a lithographic patterning device such that they are reflected by the patterning device,
using an imaging detector to detect spatial positions of the radiation beams after they have been reflected by the patterning device, and
monitoring the spatial positions of the radiation beams and thereby determining the presence of a patterning device deformation,
wherein the imaging detector has an collection angle which is smaller than a minimum angle of diffraction of the radiation beams.

16. A deformation monitoring apparatus to monitor for deformation of a patterning device, the patterning device being a lithographic patterning device, and the apparatus comprising:
a radiation source configured to direct a plurality of beams of radiation with a predetermined diameter towards the patterning device such that a corresponding plurality of reflected radiation beams are provided by reflection by the patterning device,
an imaging detector configured to detect spatial positions of the reflected radiation beams, and
a processor configured to monitor the spatial positions of the reflected radiation beams and thereby determine a presence of a patterning device deformation,
wherein the imaging detector has a collection angle which is smaller than a minimum angle of diffraction by the patterning device of a diffracted radiation beam associated with at least one of the plurality of beams of radiation directed towards the patterning device.

17. A lithographic patterning device deformation monitoring apparatus comprising:
a radiation source configured to direct a plurality of beams of radiation with a predetermined diameter towards a lithographic patterning device such that they are reflected as a corresponding plurality of reflected beams by the lithographic patterning device,
an imaging detector configured to detect spatial positions of the reflected beams, and a processor configured to monitor spatial positions of the reflected beams at a surface of the detector, and
thereby determine a presence of a patterning device deformation,
wherein the imaging detector has a collection angle which is less than or equal to +/−5°.

18. A method of determining whether or not a patterning device is suffering from deformation, the method comprising:
directing a plurality of beams of radiation towards the lithographic patterning device such that they are reflected as a corresponding plurality of reflected beams by the patterning device,
using an imaging detector to detect spatial positions of the reflected radiation beams, and
monitoring spatial positions of the reflected radiation beams at a surface of the detector and thereby determining a presence of a patterning device deformation,
Wherein the imaging detector has an collection angle Which is smaller than a minimum angle of diffraction by the patterning device of a diffracted radiation beam associated with at least one of the plurality of beams of radiation directed towards the patterning device.
